(19) United States
(12) Patent Application Publication
(10) Pub. No.: US 2026/0206180 A1
(43) Pub. Date: Jul. 16, 2026

(54) FLOW OPTIMIZATION SYSTEM AND METHOD FOR IMMERSION COOLING OF COMPUTING SYSTEMS

(71) Applicant: Quanta Computer Inc., Taoyuan City (CN)

(72) Inventors: Yi-Chieh CHEN, Taoyuan City (CN); Yueh-Chang WU, Taoyuan City (CN); Te-Chuan WANG, Taoyuan City (CN); Tzu-Hsuan HSU, Taoyuan City (CN); Tzu-Chun YANG, Taoyuan City (CN)

(21) Appl. No.: 19/016,029

(22) Filed: Jan. 10, 2025

(51) Int. Cl. H05K 7/20

(52) U.S. Cl. CPC H05K 7/20272; H05K 7/20236; H05K 7/20281; H05K 7/20763

(57) ABSTRACT

A computing system includes an immersion cooling system and computing devices. Each computing device has heat-generating components. The immersion cooling system includes a coolant distribution unit fluidly coupled with a cooling tank. The coolant distribution unit circulates a coolant through the cooling tank. The cooling tank includes device-cooling guides that are immersed in the coolant. Each device-cooling guide includes a solenoid valve and an open channel. The solenoid valve controls the coolant flowing through the device-cooling guide. The open channel is structurally coupled and in fluid communication with the solenoid valve. The open channel is designed to receive a computing device and direct the coolant in a cooling path over the computing device, thus optimizing immersion cooling by minimizing or eliminating coolant bypass flows otherwise present in prior computing systems with immersion cooling.

### FIELD OF THE INVENTION

The present invention relates generally to a computing system, and more specifically, to a flow optimization system and method for immersion cooling of computing systems.

### BACKGROUND OF THE INVENTION

As new technologies rapidly improve the efficiency and capability of computing systems, energy consumption presents a significant challenge for thermal management. Key components used in the Internet Technology (IT), such as central processing units (CPUs) and graphical processing units (GPUs), are quickly exceeding 1,500 Watts. Traditional airflow cooling technologies may be insufficient for these power intensive components. Immersion cooling using liquids, especially open bath immersion cooling, has emerged as an energy efficient technology that can improve the overall performance of IT components and systems. In most open bath systems, a coolant distribution unit circulates a coolant through a cooling tank. Within the cooling tank, heat-generating IT components such as servers are submerged in the coolant that is generally directed by a perforated lower plate. In these prior systems, most cooling tanks do not have individual channels for the IT components. Thus, the coolant flows over the IT components include uneven and bypass flows that are detrimental to the overall cooling efficiency of the system.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a computing system with immersion cooling has one or more computing devices. Each of the one or more computing devices has at least one heat-generating component. The computing system further includes a coolant distribution unit and a cooling tank. The coolant distribution unit is designed to circulate a coolant through the cooling tank. The cooling tank is fluidly coupled with the coolant distribution unit to receive the coolant. The cooling tank includes one or more device-cooling guides that are immersed in the coolant. Each of the one or more device-cooling guides includes a solenoid valve and an open channel. The solenoid valve is designed to circulate the coolant through the one or more device-cooling guides. The open channel is structurally coupled and in fluid communication with the solenoid valve. Moreover, the open channel is designed to receive a respective one of the one or more computing devices and direct the coolant in a cooling path over the one or more computing devices to achieve a uniform coolant flow without bypass flows.

According to one aspect of the present disclosure, the open channel is designed to receive only a portion of the respective one of the one or more computing devices within the open channel.

According to another aspect of the present disclosure, the one or more device-cooling guides includes a plurality of device-cooling guides. Each of the plurality of device-cooling guides is mounted generally parallel to another one of the plurality of device-cooling guides.

According to a configuration of the above implementation, the solenoid valve is coupled to a bottom plate of the open channel.

According to another configuration of the above implementation, the open channel is defined by a first wall, a second wall, and a bottom plate. Each of the first wall and the second wall is terminally coupled to the bottom plate. Additionally, the first wall and the second wall are positioned opposite each other to define the open channel.

According to a further configuration of the above implementation, the open channel further includes a first spring plate. The first spring plate is mounted on the first wall and positioned within the open channel.

In a further aspect of the above implementation, the first spring plate has a surface curved away from the first wall.

In yet a further aspect of the above implementation, the open channel further includes a second spring plate. The second spring plate is mounted on the second wall and positioned within the open channel.

According to another aspect of the present disclosure, the second spring plate has a surface curved away from the second wall.

According to a configuration of the above implementation, each of the first wall and the second wall includes an angled edge. The angled edge is distally positioned thereon and opposite the bottom plate. Moreover, the angled edge is oriented in an angle away from the open channel.

According to another configuration of the above implementation, the bottom plate is a perforated plate.

According to a further configuration of the above implementation, the one or more of the computing devices is a server.

According to yet another aspect of the present disclosure, a computing system includes an immersion cooling system and one or more computing devices. Each of the one or more computing devices has at least one heat-generating component. The immersion cooling system has a coolant distribution unit for circulating a coolant. Additionally, the immersion cooling system includes a cooling tank. The cooling tank is fluidly coupled with the coolant distribution unit to receive the coolant. Moreover, the cooling tank includes one or more device-cooling guides immersed in the coolant. Each of the one or more device-cooling guides includes a solenoid valve and an open channel. The solenoid valve is designed to control the circulation of the coolant. The open channel is structurally coupled and in fluid communication with the solenoid valve. Additionally, the open channel is configured to receive a respective one of the one or more computing devices. Further, the open channel directs the coolant in a cooling path over the respective one of the one or more computing devices.

According to a configuration of the above implementation, the computing system further includes a memory device and a control system. The memory device has stored thereon machine-readable instructions. The control system is communicatively connected with the solenoid valve, the coolant distribution unit, and a baseboard management controller of the respective one of the one or more computing devices. Additionally, the control system has one or more processors configured to execute the machine-readable instructions to cause the computing system to: (i) open the solenoid valve if a temperature of the respective one of the one or more computing devices exceeds a predetermined value determined by the baseboard management controller; and (ii) using the coolant distribution unit, flow the coolant through the open channel and the respective one of the one or more computing devices.

According to another configuration of the above implementation, the computing system further includes a sensor that is mounted on the open channel and communicatively coupled to the control system. Moreover, the control system is configured to cause the computing system to close the solenoid valve if the open channel is vacant, as determined by the sensor.

According to a further configuration of the above implementation, the control system is configured to cause the computing system to open the solenoid valve to a percentage of a full opening. The percentage is a value in a range between about 0.1% to about 100% of the full opening, based on a temperature difference between the temperature of the respective one of the one or more computing devices and the predetermined value.

In a further aspect of the above implementation, a method is provided for cooling a computing system that has one or more computing devices. The method includes: (i) obtaining an immersion cooling system that has a coolant distribution unit and a cooling tank, wherein the cooling tank is fluidly coupled to the coolant distribution unit to receive a coolant; (ii) mounting one or more device-cooling guides within the cooling tank; (iii) mounting a solenoid valve to each of the one or more device-cooling guides; (iv) fluidly coupling the solenoid valve to an open channel of each of the one or more device-cooling guides; (v) receiving, in the open channel, a respective one of the one or more computing devices; and (vi) through the open channel, flowing the coolant in a cooling path over the respective one of the one or more computing devices if the solenoid valve is opened.

According to a configuration of the above implementation, the method further includes: (a) mounting a sensor to the open channel; (b) determining by the sensor that the open channel is vacant; and (c) based on the determining, closing the solenoid valve.

According to another configuration of the above implementation, the method further includes closing the solenoid valve if a temperature of the respective one of the one or more computing devices is at or below a predetermined value determined by a baseboard management controller thereof.

According to a further configuration of the above implementation, the method includes opening the solenoid valve to a percentage of a full opening. The percentage is a value in a range between about 0.1% to about 100% of the full opening. Moreover, the percentage is determined based on a temperature difference between a temperature of the respective one of the one or more computing devices and a predetermined value. Further, the predetermined value is determined by a baseboard management controller of the respective one of the one or more computing devices.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a front view showing a computing system with immersion cooling for one or more computing devices therein, according to certain aspects of the present disclosure.

FIG. 1P is front view showing a prior computing system with immersion cooling for one or more computing devices therein.

FIG. 2 is front view showing a computing system with immersion cooling for one or more computing devices each having at least one heat-generating component and a baseboard management controller, according to certain aspects of the present disclosure.

FIG. 3 is a front view showing a device-cooling guide coupled with a solenoid valve of the computing system, according to certain aspects of the present disclosure.

FIG. 4 is a diagram showing electrical connections and data flow of a control system of the computing system, according to certain aspects of the present disclosure.

FIG. 5 is a flowchart diagram showing a process for cooling the one or more computing devices by the control system, according to certain aspects of the present disclosure.

FIG. 6 is a flowchart diagram showing a method for cooling a computing system by use of one or more device-cooling guides, each coupled with a solenoid valve, according to certain aspects of the present disclosure.

FIG. 7 is a flowchart diagram showing sub-processes for cooling the computing system by controlling the solenoid valve, according to certain aspects of the present disclosure.

FIG. 8 is a flowchart diagram showing a sub-process for cooling the computing system by use of a sensor mounted on each of the one or more device-cooling guides, according to certain aspects of the present disclosure.

### DETAILED DESCRIPTION

A computing system and method are designed to overcome the drawbacks of open bath cooling of Internet Technology (IT) components and systems. The computing system includes an immersion cooling system and computing devices. Each computing device has heat-generating components such as central processing units (CPUs) and graphical processing units (GPUs). The immersion cooling system includes a coolant distribution unit fluidly coupled with a cooling tank. The coolant distribution unit circulates a coolant through the cooling tank. The cooling tank includes device-cooling guides that are immersed in the coolant. Each device-cooling guide includes a solenoid valve and an open channel. The solenoid valve controls the coolant flowing through the device-cooling guide. The open channel is structurally coupled and in fluid communication with the solenoid valve. The open channel is designed to receive a computing device and direct the coolant in a uniform cooling path over the computing device. Thus, the computing system optimizes immersion cooling by minimizing or eliminating coolant bypass flows otherwise existed in the prior computing systems with immersion cooling. Moreover, the computing system is designed to provide on/off and/or precise proportional control of the coolant flow, via the solenoid valve, for any component installed on the device-cooling guide to reduce energy consumption. Further, the device-cooling guide is designed to provide efficient installation of the IT component such as a server to improve the operation efficiency of the computing system.

The method of providing the computing system with immersion cooling includes the use of a sensor that is mounted to the device-cooling guide. The sensor is designed to detect the IT component when installed in the device-cooling guide. If the device-cooling guide is vacant, e.g., no IT component installed therein, the method shuts off the solenoid valve. For a server with a baseboard management controller, the method provides precise control of the coolant flow over the server. In this case, the method compares the server temperature detected by the baseboard management controller with a predetermined temperature. Subsequently, the method opens the solenoid valve proportional to the full opening thereof based on the resulting temperature difference. Thus, the method provides optimization of the precise coolant flow required to cool the server to the predetermined temperature.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

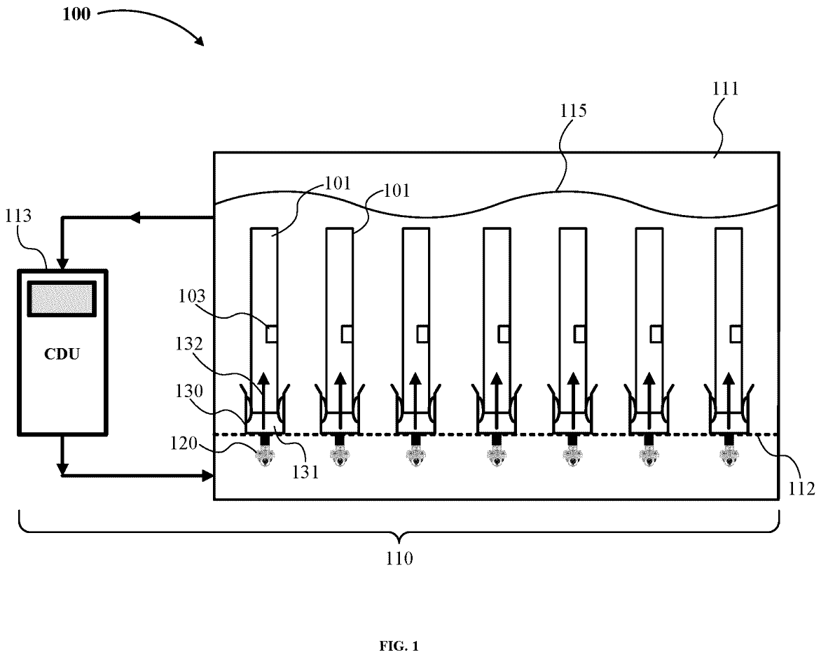

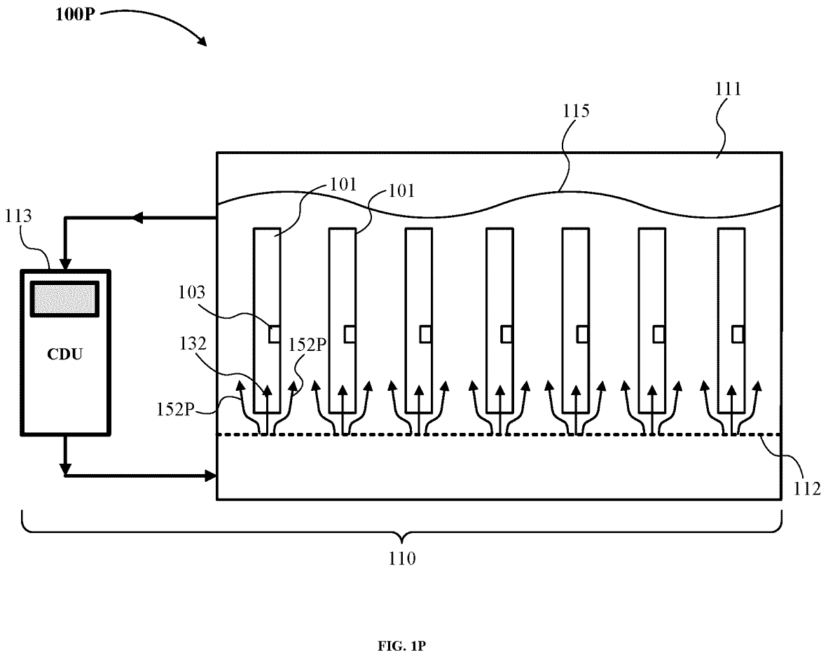

FIG. 1 illustrates a computing system 100 with immersion cooling. The computing system 100 includes one or more computing devices 101, each having at least one heat-generating component 103. For example, in a typical computing system 100, the at least one heat-generating component 103 is a microprocessor such as a central processing unit (CPU), a graphical processing unit (GPU), a power supply, a baseboard management controller (BMC), a memory, a storage device, a fan module, or any other component. Moreover, in some implementations, the one or more computing devices 101 is a server.

The computing system 100 includes an immersion cooling system 110 to facilitate immersion cooling. Specifically, the immersion cooling system 110 includes a cooling tank 111 and a coolant distribution unit (CDU) 113. The coolant distribution unit 113 is designed to circulate a coolant 115. The cooling tank 111 is fluidly coupled with the coolant distribution unit 113 to receive the coolant 115. Moreover, the cooling tank 111 has a lower plate 112 that is position at a lower portion of the cooling tank 111. In some implementations, the coolant 115 is a dielectric liquid. The coolant 115 includes, but is not limited to, mineral oil, synthetic oil, fluorocarbon liquid, silicone fluid, single-phase thermally conductive dielectric liquid, or any combination thereof. For example, the coolant 115 is a polyalphaolefin 4 (PAO 4) liquid.

As shown in FIG. 1, the computing system 100 includes one or more device-cooling guides 130. The one or more device-cooling guides 130 defines an open channel 131 that receives a respective computing device of the one or more computing devices 101. For example, the open channel 131 receives only a portion of the respective computing devices 101. Moreover, each of the one or more device-cooling guides 130 is mounted on the lower plate 112 of the cooling tank 111. Further, the respective computing devices 101 is removably attached to the open channel 131 opposite the lower plate 112.

The computing system 100 also includes a solenoid valve 120. The solenoid valve 120 is designed to circulate the coolant 115 between the cooling tank 111 and the coolant distribution unit 113. As shown in FIG. 1, the open channel 131 is structurally and fluidly coupled to the solenoid valve 120. In some implementations, the solenoid valve 120 is positioned within the cooling tank 111. Moreover, the solenoid valve 120 is attached to the open channel 131 via the lower plate 112. The solenoid valve 120 is configured to provide open, close, and/or precise flow control of the coolant 115 through the open channel 131. Subsequently, the open channel 131 directs the coolant 115 upward to uniformly distribute a coolant flow in a cooling path 132 over the one or more computing devices 101. The upward flow of the coolant 115, illustrated by the cooling path 132, effectively removes heat generated by the at least one heat-generating component 103 of the one or more computing devices 101. For example, the heat exchange between the coolant 115 and the one or more computing devices 101 is effectuated by convection heat transfer. Since the one or more computing devices 101 is aligned with the open channel 131, the cooling path 132 is optimal in providing efficient cooling with minimal or no bypass flows around the one or more computing devices 101.

FIG. 1P shows a prior art computing system 100P with immersion cooling. Similar to the computing system 100 in FIG. 1, the prior art computing system 100P has the immersion cooling system 110 that includes the cooling tank 111 and the coolant distribution unit 113. The coolant distribution unit 113 is fluidly coupled to and circulates the coolant 115 through the cooling tank 111. Additionally, the prior art computing system 100 has the one or more computing devices 101 that are removably mounted within the cooling tank 111. The one or more computing devices 101 has at least one heat-generating component 103. Further, the cooling tank 111 has the lower plate 112 that is perforated. The lower plate 112 is attached within the cooling tank 111 and positioned below the one or more computing devices 101, as shown in FIG. 1P. The one or more computing devices 101 are submerged in the coolant 115. The coolant 115 is directed upward through the lower plate 112 and to flow over the one or more computing devices 101. The upward flows of the coolant 115 include at least (1) the cooling path 132, and (2) bypass flows 152P.

FIG. 1P is different than FIG. 1 in that the prior art computing system 100P does not have the one or more device-cooling guides 130 and the solenoid valve 120. Because of lack of the one or more device-cooling guides 130 to direct the flow of the coolant 115, the bypass flows 152P occur in the prior computing system 100P, as shown in FIG. 1P. The bypass flows 152P significantly reduce the total amount of the coolant 115 flowing uniformly and directly over the one or more computing devices 101, thus resulting in inefficient heat removal of the at least one heat-generating component 103 of the one or more computing devices 101.

In the computing system 100, the open channel 131 of each of the one or more device-cooling guides 130 directs the coolant 115 to flow upward and uniformly over the one or more computing devices 101. Thus, the open channel 131 optimizes the coolant flow by minimizing and/or eliminating bypass flows around the over the one or more computing devices 101. This optimization is estimated to significantly minimize the bypass flow, thus improving cooling efficiency of the prior computing system 100P.

For example, an analysis was conducted using a computational fluid dynamic (CFD) simulation for the computing system 100 and the prior computing system 100P. Both systems include: (i) the same number of computing devices, e.g., seven two-unit-two-processor (2U2P) servers; (ii) each computing device has the same heat-generating device, e.g., a central processing unit (CPU); (iii) the same coolant, PAO-4; and (iv) the same inflow coolant temperature, 40° C. Comparing with the prior computing system 100P in FIG. 1P, the analysis results showed that the computing system 100, as shown in FIG. 1, (a) reduced the total bypass flow 152P by at least 20%, (b) achieved a total bypass flow below 5% of the total coolant flow over one or more computing devices 101, and (c) reduced the temperature of the central processing unit (CPU) by more than 2° C.

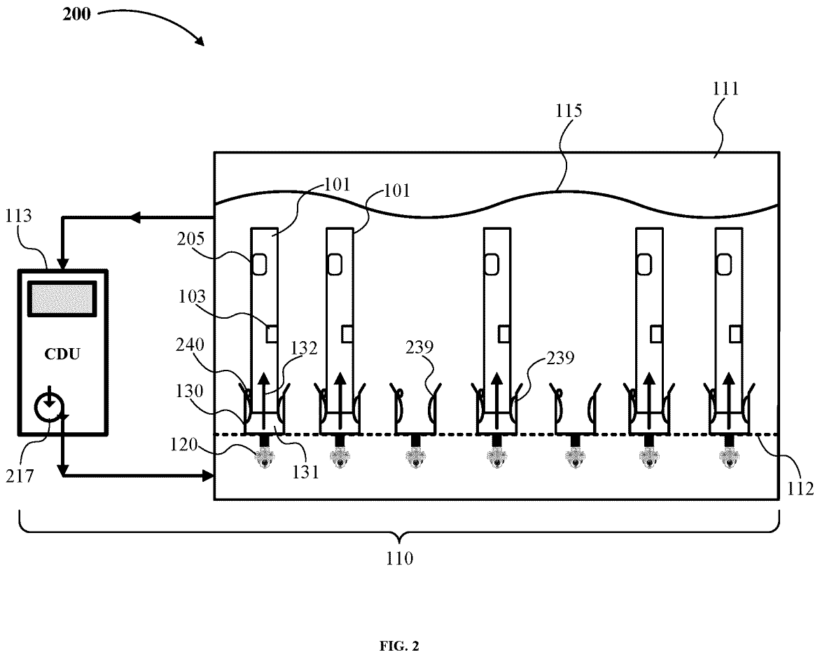

FIG. 2 shows a computing system 200 with immersion cooling for the one or more computing devices 101. The computing system 200 has an immersion cooling system 110 that includes a cooling tank 111 and a coolant distribution unit 113. The coolant distribution unit 113 has a pump 217 designed to circulate a coolant 115 inside the cooling tank 111. The cooling tank 111 is fluidly coupled with the coolant distributing unit 113 to receive the coolant 115. Additionally, the cooling tank 111 has a lower plate 112 positioned within the cooling tank 111. In some implementations, the lower plate 112 is a perforated plate that allows the coolant 115 flowing through the lower plate 112. The solenoid valve 120 is coupled to the lower plate 112. Moreover, the solenoid valve 120 is positioned within the cooling tank 111 to circulate the coolant 115. Further, each of the one or more computing devices 101 has a baseboard management controller 205 and the at least one heat-generating component 103.

As shown in FIG. 2, the computing system 200 includes one or more device-cooling guides 130 that are mounted to the lower plate 112. Each of the one or more device-cooling guides 130 includes the open channel 131. The open channel 131 is structurally coupled and in fluid communication with the solenoid valve 120. Both the open channel 131 and the solenoid valve 120 are immersed in the coolant 115. The open channel 131 is designed to receive a respective one of the one or more computing devices 101 such that the one or more computing devices 101 is removably secured on the open channel 131 of the one or more device-cooling guides 130. In some implementations, the open channel 131 receives only a portion of the respective one of the one or more computing devices 101. The respective one of the one or more computing devices 101 is also immersed in the coolant 115. Moreover, when the solenoid valve 120 is open, the coolant distribution unit 113 flows through the coolant 115 by the pump 217. The coolant 115 flows upward through the lower plate 112 and into the open channel 131. The coolant 115 is subsequently directed by the open channel 131 in the cooling path 132 over the respective one of the one or more computing devices 101. The coolant flow via the cooling path 132 substantially reduces the bypass flows and improves cooling efficiency of the respective one of the one or more computing devices 101.

As shown in FIG. 2, the computing system 200 includes a sensor 240 that is mounted on the open channel 131. The sensor 240 is designed to detect the respective one of the one or more computing devices secured in the open channel 131. When the sensor 240 does not detect the respective one of the one or more computing devices, e.g., the open channel 131 being vacant, the solenoid valve is then closed to prevent coolant 115 from flowing through the open channel 131. Thus, the sensor 240 is designed to improve energy efficiency of immersion cooling of the computing system 200.

In some implementations, the one or more device-cooling guides 130 include a plurality of device-cooling guides 239. Specifically, each of the plurality of device-cooling guides 239 is mounted generally parallel to another one of the plurality of device-cooling guides 239, as shown in FIG. 2.

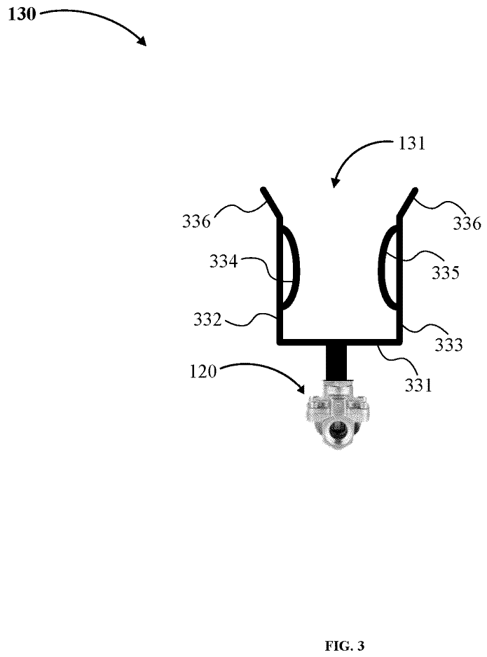

FIG. 3 shows that the one or more device-cooling guides 130 is coupled with the solenoid valve 120 of the computing systems 100 and 200. The one or more device-cooling guides 130 includes the open channel 131. The open channel 131 includes a bottom plate 331, a first wall 332, a second wall 333. The bottom plate 331 is attached to the lower plate 112 of the cooling tank 111. In some implementations, the bottom plate 331 is a perforated plate. The first wall 332 and the second wall 333 are terminally coupled to the bottom plate 331. Additionally, the first wall 332 and the second wall 333 are positioned opposite each other to define the open channel 131. Each of the first wall 332 and the second wall 333 has an angled edge 336. The angled edge 336 is distally positioned thereon and opposite the bottom plate 331. Moreover, the angled edge 336 is oriented in an angle away from the open channel 131. The angled edge 336 for each of the first wall 332 and the second wall 333 is designed to facilitate efficient installation of the respective one or more computing devices 101 on the open channel 131 of the one or more device-cooling guides 130.

As shown in FIG. 3, the open channel 131 includes a first spring plate 334 and a second spring plate 335. The first spring plate 334 is mounted on the first wall 332 and positioned within the open channel 131. Similarly, the second spring plate 335 is mounted on the second wall 333 and positioned within the open channel 131. In some implementations, the first spring plate 334 and the second spring plate 335 each have a surface curved away therefrom and towards a center of the open channel 131. Both first spring plate 334 and the second spring plate 335 are designed to secure the respective one or more computing devices 101 on the open channel 131. Such a configuration also ensures proper alignment of the respective one or more computing devices 101 on the open channel 131 so that the coolant 115 is directed over the respective one or more computing devices 101 with no or minimum bypass flows.

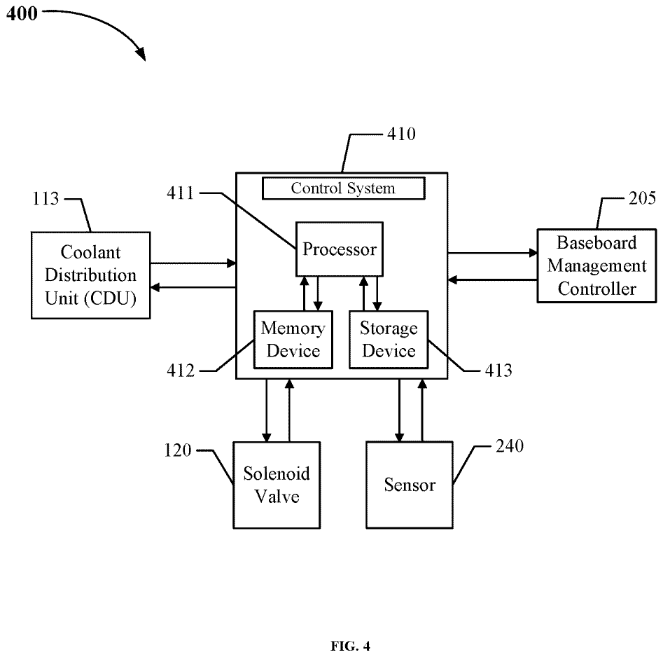

FIG. 4 shows electrical connections and data flows of a control system 410 of a computing system 400 with immersion cooling. The control system 410 is electrically connected and in communications with the coolant distribution unit 113, the solenoid valve 120, the sensor 240, and the baseboard management controller 205. Additionally, the control system 410 includes one or more processors 411, a memory device 412, and a storage device 413. The memory device 412 has machine-readable instructions or algorithms that are designed to control flows of the coolant 115 circulating in the cooling tank 111.

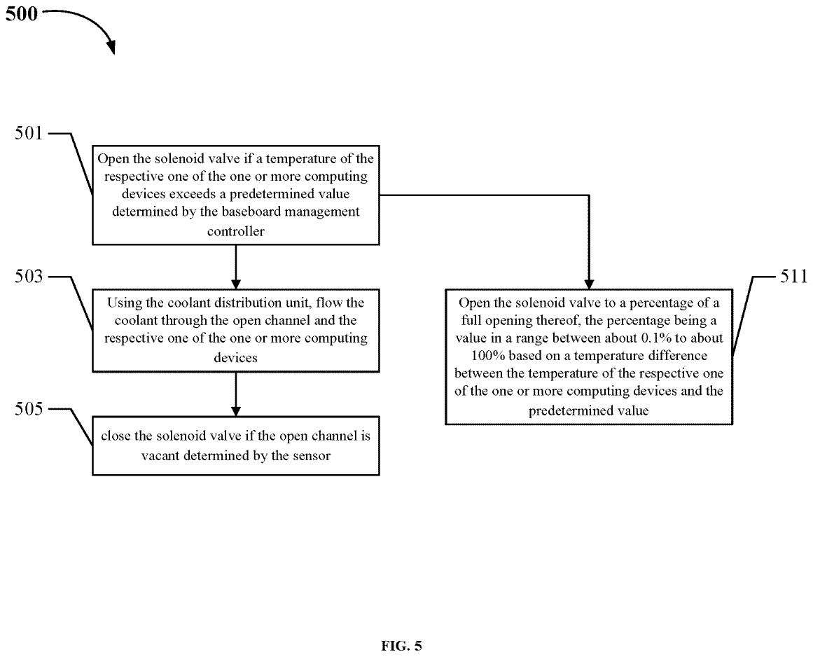

FIG. 5 shows a process 500 for cooling the one or more computing devices 101 by the control system 410. Specifically, the one or more processors 411 of the control system 410 executes the machine-readable instructions to cause the computing system 200 to: (1) open the solenoid valve 120 if a temperature of the respective one of the one or more computing devices 101 exceeds a predetermined value determined by the baseboard management controller 205 (Step 501); and (2) using the coolant distribution unit 113, flow the coolant 115 through the open channel 131 and the respective one of the one or more computing devices 101 (Step 503). In Step 501, the predetermined value for the temperature of the respective one of the one or more computing devices 101, for example, is 40° C. In some implementations, the predetermined value is a temperature in the range of 40° C. to 50° C.

As shown in FIG. 5, the control system 410 is configured to cause the computing system 400 to close the solenoid valve 120 if the open channel 131 is vacant, as determined by the sensor 240 (Step 505). The sensor 240 is mounted on the open channel 131 and designed to detect the respective one of the one or more computing devices 101 installed to the open channel 131 of the one or more device-cooling guides 130, as shown in FIG. 2. The sensor 240 communicates with the control system 410 to control to open/close the solenoid valve 120. When an open channel 131 of any one of the one or more device-cooling guides 130 is detected to be vacant, the control system 410 closes the solenoid valve 120 that is fluidly coupled to the open channel 131. Thus, the total energy consumption of the computing system 400 is reduced compared to a computing system that does not have such controls.

Moreover, the control system 410 is configured to cause the computing system 400 to open the solenoid valve 120 to a percentage of a full opening when cooling the respective one of the one or more computing devices 101 (Step 511). The percentage is a value in a range between about 0.1% to about 100% based on a temperature difference between the temperature of the respective one of the one or more computing devices 101 and the predetermined value. This process provides a precise control of the coolant flow to not only achieve a desired temperature of the respective one of the one or more computing devices 101, but also improve the energy efficiency of the immersion cooling of the computing system 400.

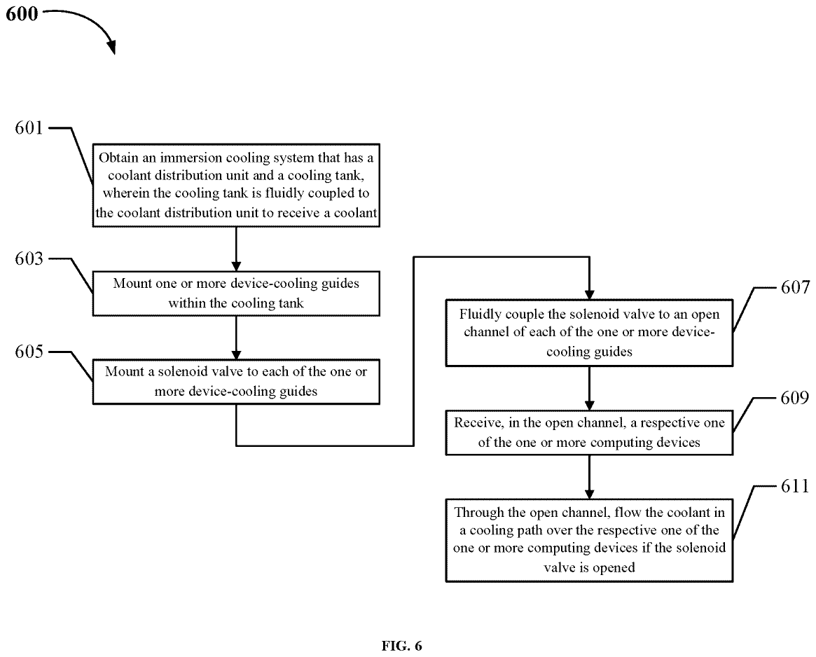

FIG. 6 shows a method 600 for cooling a computing system by use of one or more device-cooling guides, each coupled with a solenoid valve. Specifically, the method 600 includes: (i) obtaining an immersion cooling system that has a coolant distribution unit and a cooling tank, wherein the cooling tank is fluidly coupled to the coolant distribution unit to receive a coolant (Step 601); (ii) mounting one or more device-cooling guides within the cooling tank (Step 603); (iii) mounting a solenoid valve to each of the one or more device-cooling guides (Step 605); (iv) fluidly coupling the solenoid valve to an open channel of each of the one or more device-cooling guides (Step 607); (v) receiving, in the open channel, a respective one of the one or more computing devices (Step 609); and (vi) through the open channel, flowing the coolant in a cooling path over the respective one of the one or more computing devices if the solenoid valve is opened (Step 611).

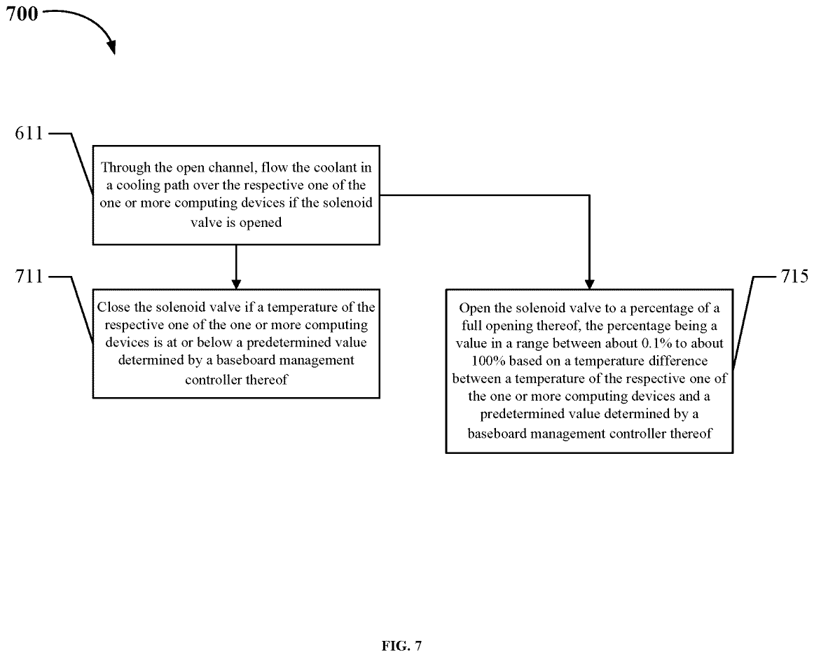

FIG. 7 shows sub-processes for cooling the computing system by controlling the solenoid valve. First, the method 700 includes a sub-process for closing the solenoid valve if a temperature of the respective one of the one or more computing devices is at or below a predetermined value determined by a baseboard management controller thereof (Step 711). In this sub-process, the predetermined value for the temperature of the respective one of the one or more computing devices is about 40° C. In some implementations, the predetermined value is a temperature in a range of about 40° C. to about 50° C., or about 40° C. to about 89° C.

Second, the method 700 includes another sub-process for opening the solenoid valve to a percentage of a full opening. The percentage is a value in a range between about 0.1% to about 100% of the full opening. Moreover, the percentage is determined based on a temperature difference between a temperature of the respective one of the one or more computing devices and a predetermined value. Further, the predetermined value is determined by a baseboard management controller of the respective one of the one or more computing devices (Step 715).

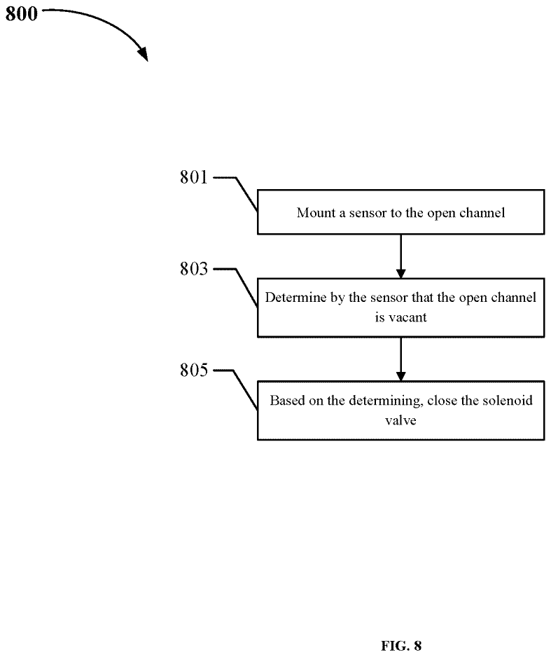

FIG. 8 shows a sub-process 800 of the method 700 for cooling the computing system by use of a sensor mounted on each of the one or more device-cooling guides. Specifically, the sub-process 800 includes: (a) mounting a sensor to the open channel (Step 801); (b) determining by the sensor that the open channel is vacant (Step 803); and (c) based on the determining, closing the solenoid valve (Step 805). In this sub-process 800, the method 700 uses the sensor to detect if there is a computing system installed in a respective one of the one or more device-cooling guides. The method 700 closes the solenoid valve if the respective one of the one or more device-cooling guides is vacant, thus saving the energy of circulating the coolant that the computing system would otherwise have consumed.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above-described embodiments. Rather, the scope of the disclosure should be defined in accordance with the following claims and their equivalents.

What is claimed is:

1. A computing system with immersion cooling, the computing system comprising:
one or more computing devices, each of the one or more computing devices having at least one heat-generating component;
a coolant distribution unit for circulating a coolant; and
a cooling tank fluidly coupled with the coolant distribution unit to receive the coolant, the cooling tank including one or more device-cooling guides immersed in the coolant, each of the one or more device-cooling guides including:
a solenoid valve for circulating the coolant; and
an open channel structurally coupled and in fluid communication with the solenoid valve, the open channel being configured to receive a respective one of the one or more computing devices, the open channel directing the coolant in a cooling path over the respective one of the one or more computing devices.

2. The computing system of claim 1, wherein the open channel receives therewithin a portion of the respective one of the one or more computing devices.

3. The computing system of claim 1, wherein the one or more device-cooling guides include a plurality of device-cooling guides, each of the plurality of device-cooling guides being mounted generally parallel to another one of the plurality of device-cooling guides.

4. The computing system of claim 1, wherein the solenoid valve is coupled to a bottom plate of the open channel.

5. The computing system of claim 1, wherein the open channel is defined by a first wall, a second wall, and a bottom plate, the first wall and the second wall each being terminally coupled to the bottom plate, the first wall and the second wall being positioned opposite each other to define the open channel.

6. The computing system of claim 5, wherein the open channel further includes a first spring plate, the first spring plate being mounted on the first wall and positioned within the open channel.

7. The computing system of claim 6, wherein the first spring plate has a surface curved away from the first wall.

8. The computing system of claim 5, wherein the open channel further includes a second spring plate, the second spring plate being mounted on the second wall and positioned within the open channel.

9. The computing system of claim 8, wherein the second spring plate has a surface curved away from the second wall.

10. The computing system of claim 5, wherein each of the first wall and the second wall includes an angled edge, the angled edge being distally positioned thereon and opposite the bottom plate, the angled edge being oriented in an angle away from the open channel.

11. The computing system of claim 5, wherein the bottom plate is a perforated plate.

12. The computing system of claim 1, wherein the one or more of the computing devices is a server.

13. A computing system comprising:
one or more computing devices, each of the one or more computing devices having at least one heat-generating component; and
an immersion cooling system having a coolant distribution unit for circulating a coolant and a cooling tank, the cooling tank fluidly coupled with the coolant distribution unit to receive the coolant, the cooling tank including one or more device-cooling guides immersed in the coolant, and each of the one or more device-cooling guides including:
a solenoid valve for circulating the coolant; and
an open channel structurally coupled and in fluid communication with the solenoid valve, the open channel being configured to receive a respective one of the one or more computing devices, the open channel directing the coolant in a cooling path over the respective one of the one or more computing devices.

14. The computing system of claim 13, further comprising:
a memory device having stored thereon machine-readable instructions; and
a control system communicatively connected with the solenoid valve, the coolant distribution unit, and a baseboard management controller of the respective one of the one or more computing devices, and wherein the control system having one or more processors configured to execute the machine-readable instructions to cause the computing system to:
open the solenoid valve if a temperature of the respective one of the one or more computing devices exceeds a predetermined value determined by the baseboard management controller; and
using the coolant distribution unit, flow the coolant through the open channel and the respective one of the one or more computing devices.

15. The computing system of claim 14, further comprising:
a sensor mounted on the open channel, the sensor communicatively coupled to the control system, and wherein the control system is configured to cause the computing system to close the solenoid valve if the open channel is vacant, as determined by the sensor.

16. The computing system of claim 14, wherein the control system is configured to cause the computing system to open the solenoid valve to a percentage of a full opening thereof, the percentage being a value in a range between about 0.1% to about 100% based on a temperature difference between the temperature of the respective one of the one or more computing devices and the predetermined value.

17. A method for cooling a computing system having one or more computing devices, comprising:
obtaining an immersion cooling system that has a coolant distribution unit and a cooling tank, wherein the cooling tank is fluidly coupled to the coolant distribution unit to receive a coolant;
mounting one or more device-cooling guides within the cooling tank;
mounting a solenoid valve to each of the one or more device-cooling guides;
fluidly coupling the solenoid valve to an open channel of each of the one or more device-cooling guides;
receiving, in the open channel, a respective one of the one or more computing devices; and
through the open channel, flowing the coolant in a cooling path over the respective one of the one or more computing devices if the solenoid valve is opened.

18. The method of claim 17, further comprising:
mounting a sensor to the open channel;
determining by the sensor that the open channel is vacant; and
based on the determining, closing the solenoid valve.

19. The method of claim 17, further comprising:
closing the solenoid valve if a temperature of the respective one of the one or more computing devices is at or below a predetermined value determined by a baseboard management controller thereof.

20. The method of claim 17, further comprising:
opening the solenoid valve to a percentage of a full opening thereof, the percentage being a value in a range between about 0.1% to about 100% based on a temperature difference between a temperature of the respective one of the one or more computing devices and a predetermined value determined by a baseboard management controller thereof.
